(19) United States
(12) Patent Application Publication
(10) Pub. No.: US 2013/0027117 A1
(43) Pub. Date: Jan. 31, 2013

(54) Precision voltage clamp with very low temperature drift

(71) Applicant: David Elliot Dorfan, Santa Cruz, CA (US)

(72) Inventor: David Elliot Dorfan, Santa Cruz, CA (US)

(73) Assignee: Anadyne, Inc.

(21) Appl. No.: 13/373,417

(22) Filed: Nov. 14, 2011

Related U.S. Application Data
(60) Provisional application No. 61/574,257, filed on Jul. 28, 2011.

(51) Int. Cl. H01L 35/00

(52) U.S. Cl. 327/513

(57) ABSTRACT

A precision voltage clamp is provided that displays virtually no temperature dependence, and maintains a clamp voltage that varies by about 1 my for input voltages ranging from the onset of clamping to several volts above this input. In particular, a current mirror is used to ensure that the current densities in the clamping transistor, and the bias correcting transistor, are very close to equal once the clamping action begins. A small current may be injected into the programming side of the mirror which will turn on the mirror and the biasing transistor, making it much easier for the clamp to clamp and settle.

### CROSS REFERENCE TO RELATED APPLICATIONS

This application is related to and claims priority from U.S. Provisional Patent Application 61/574,257, filed Jul. 28, 2011.

### BACKGROUND OF THE INVENTION

1. Technical Field

This invention relates to electronic circuits which utilize transistors to provide a precision voltage clamp that displays virtually no temperature dependence, and maintains a clamp voltage that varies by about 1 my for input voltages ranging from the onset of clamping to several volts above this input. In particular, a current mirror is used to ensure that the current densities in the clamping transistor, and the bias correcting transistor are very close to equal once the clamping action begins.

2. Background Art

A clamp is a device or sub-circuit used to limit the voltage excursions at a point in an electronic circuit. A clamp is often used to limit large pulses which could damage the input of a sensitive circuit, or cause the circuit to behave in an undesirable manner. The simplest type of clamp, as seen in FIG. 2, consists of a diode, or string of diodes, connected in series, from the point, X, where the excursion is to be limited, to a voltage source. The point X is also connected to an input voltage source through a resistor, R1. As the input voltage rises the current through the diode rises, lowering the dynamic impedance of the diode, Once this impedance becomes small compared to R1, voltage limiting at X will set in. It is not necessary to use diodes, they may be replaced by diode connected transistors or they could be the base emitter junctions of a transistor.

A simple diode clamp is sufficient for most purposes, even though the clamping voltage will vary with temperature and applied input voltage, as shown in FIG. 3(a). This figure is the output of a SPICE simulation (Simulated Program For Integrated Circuits Emphasis). The temperature dependence comes from the fact that for a fixed current through a diode, the voltage drop across the diode changes by approximately −2 mv/degree C. The rise in the clamped voltage with increasing input voltage is a result of the increase in voltage across the diode as the current through the diode increases. This rise is logarithmic at first, but becomes linear at higher input currents when the dynamic impedance drops far below the intrinsic resistance of the material from which the diode is made. This rise is far less than it would be, were the diode not there, but it can become serious, particularly in integrated circuits where the diodes, or diode connected transistors, have a substantial intrinsic resistance. However, there are cases where it is necessary to have the clamp limit at a voltage that is independent of temperature, and where the clamp voltage does not rise as the input voltage increases, i.e. the voltage at the desired point, X, needs to have the form as illustrated in FIG. 3(b).

As an example, if an approximate logarithmic transfer function is required from an amplifier, one way of achieving this is to cascade a string of amplifiers (stages), each with gain G, each of which limits at the same output voltage, and to sum the outputs of all the amplifiers in the cascade. The input may vary over several decades, and in this case, to maintain accuracy, it is essential that the limited output of a stage should be independent of the value of the input voltage for that stage, once it has acquired an input large enough to limit. Also, if the transfer function is to be temperature independent, the limiting voltages need to be temperature independent.

The problem of temperature variation can be addressed by providing a temperature compensated, rather than fixed voltage source node, Y, to connect to one end of the clamping diode. In FIG. 4, for a fixed current through Q2, the drop across the base emitter junction gets smaller as the temperature increases. The same effect is true for Q1, the clamping element. If the rate of change of voltage across the junction with temperature is the same for both junctions, then since the low impedance voltage node, Y, to which the emitter of Q1 is attached, rises by the same amount that the drop across Q1's base emitter junction decreases, the clamping voltage at X does not change. Of course it is essential to run sufficient standing current through Q2, to keep current flowing through Q2 even when maximum current is flowing through Q1. Q2 will be referred herein as the bias transistor or bias diode as appropriate.

The circuit described in the previous paragraph does overcome most of the temperature variation in the clamping voltage, as shown in FIG. 5, the result of a simulation of the circuit in FIG. 4. The four temperatures for which the simulations are shown are −40 degree C., 0 degree C., 40 degree C., and 80 degree C. However, this circuit does not solve the problem completely because the temperature dependence of the junction voltage, when a fixed current flows through it, depends on the current density, being lower for higher current density. The relative current densities for Q1 and Q2 depend on the input voltage, and thus true cancellation can occur for only one value of the input voltage as illustrated by the curves shown in FIG. 5.

The present invention provides, for the first time, a nearly ideal voltage clamp which is constructed by compensating for the voltage changes across the diode junction used to clamp the voltage, caused by temperature changes or changes in current through the clamping diode. This compensation is achieved by using a current mirror to maintain the same current density in a second diode junction for any input voltage or temperature. The second junction serves as the correction to the fixed voltage source.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out in the appended claims.

### SUMMARY OF THE INVENTION

To achieve the foregoing objectives, and in accordance with the purpose of the invention as embodied and broadly described herein, the present invention utilizes a current mirror to match the current densities in the bias, and clamping transistors, thereby ensuring that the voltages across the transistor junctions track each other when current flows through the clamping transistor, at any temperature. A current mirror is used to ensure that the current densities in the clamping transistor and the bias correcting transistor are very close to equal once the clamping action begins. What is important is the matching of the transistors, and this essentially requires that the clamp of the present invention be built as an integrated circuit, or with transistor arrays, rather than using discrete components. There are several ways of making a current mirror and some of these are described in the description of the preferred embodiments and the drawings.

### BRIEF DESCRIPTION OF DRAWINGS

The accompanying drawings, which are incorporated in and constitute a part of the specification, illustrate a preferred embodiment of the invention and, together with a general description given above and the detailed description of the preferred embodiment given below, serve to explain the principles of the invention.

FIG. 1 shows a preferred embodiment of the invention, where the current source of the first order corrected clamp shown in FIG. 4, is replaced with a current mirror, made with Q2 and Q3, so that the current through the two transistors Q1 and Q4 are the same, no matter what the current flow through Q1 is, according to the invention.

FIG. 2 shows a prior art standard clamp device or sub-circuit used to limit voltage excursions at a point in an electronic circuit, for illustrative purposes.

FIG. 3(a) shows an actual simulation of the simple clamp of FIG. 2, using SPICE, for illustrative purposes.

FIG. 3(b) shows a graph of an ideal clamp where the clamp limit is at a voltage independent of temperature, and where voltage does not rise as the input voltage increases, for illustrative purposes.

FIG. 4 shows a first order temperature compensated clamp, for illustrative purposes.

FIG. 5 shows a first order temperature compensated clamp output for which simulations are shown for −40 degrees C. 0 degrees C., 40 degrees C. and 80 degrees C., the output of a simulation for FIG. 4, for illustrative purposes.

FIG. 6 shows the results of simulation of the circuit of FIG. 1, the simulation run for four different temperatures, for −40 degrees C. 0 degrees C., 40 degrees C. and 80 degrees C. according to the invention

FIG. 7 shows another preferred embodiment of the invention using equal numbers of PNP and NPN transistors, where Y is the emitter of a transistor, according to the invention.

FIG. 8 shows the injection of bias current into the programming side of the mirror which will turn on the mirror and Q4, to lower junction impedances, according to the invention.

FIG. 9 shows a preferred embodiment of the invention with a clamp using a mirror with a helper transistor, according to the invention.

FIG. 10 shows a preferred embodiment of the invention using a Wilson mirror, according to the invention.

FIG. 11 shows another preferred embodiment of the invention of the clamp of the present invention using a Wilson mirror, and bias current injection. The circuit also utilizes a pre-clamp and low pass output filter according to the invention.

FIG. 12 shows the DC transfer curve (Vout v. Vin) over temperature from −40 degrees C. to 80 degrees C. of the clamp of the present invention.

FIG. 13 shows the response of the clamp of the present invention shown in FIG. 11, to a 3 volt input pulse, according to the invention.

FIG. 14 illustrates the response of the clamp to a 300 mv input pulse shown for the −40 degrees C., 0 degrees C., 40 degrees C., and 80 degrees C., according to the invention.

FIG. 15 shows the use of the clamp of the present invention to make a novel fast flash A/D converter with a large number of bits, according to the invention.

FIG. 16 is a flow diagram of a preferred method of creating a precision voltage clamp, according to the invention.

FIG. 17 is a flow diagram of another preferred method of creating a precision voltage clamp, according to the invention.

FIG. 18 illustrates the clamp configured for clamping positive going pulses, according to the invention.

FIG. 19 illustrates the clamp configured for clamping negative going pulses, according to the invention.

### DETAILED DESCRIPTION OF THE PREFERRED EMBODIMENTS

Reference will now be made in detail to the present preferred embodiments of the invention as illustrated in the accompanying drawings.

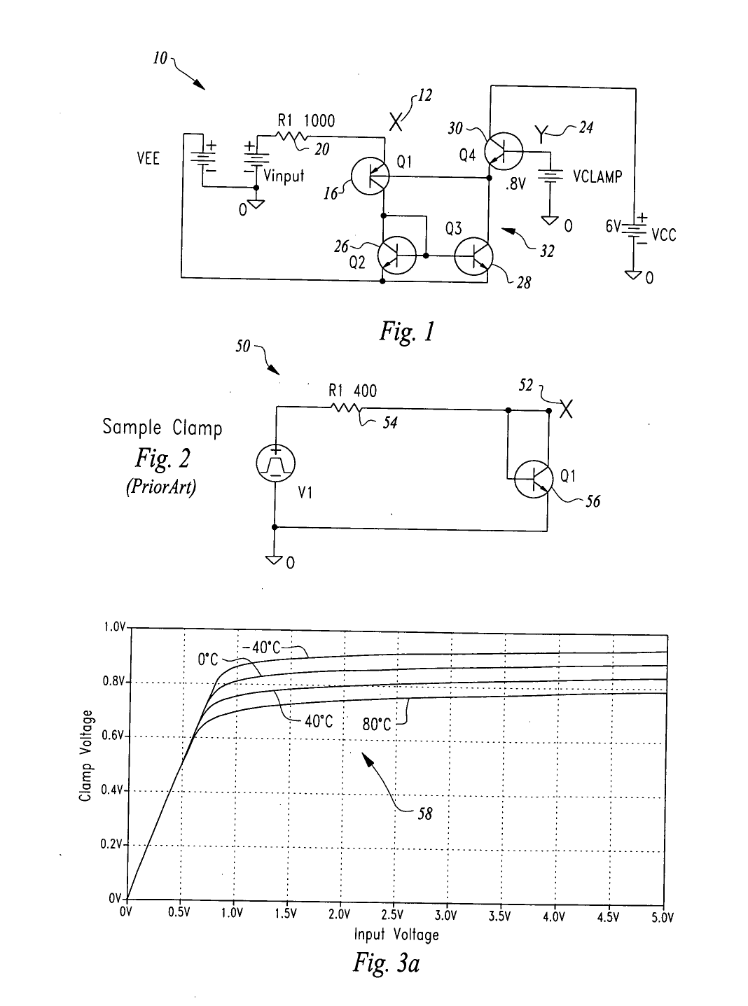

The preferred embodiments of the present invention, described herein and illustrated in the drawings, in particular FIGS. 1, 7, 8, 9, 10 and 11, provide a nearly ideal voltage clamp, constructed by compensating for the voltage changes across a diode junction used to clamp a voltage, whether caused by temperature changes or changes in current through the clamping diode junction. As seen in the accompanying drawings and described herein, this compensation is achieved as follows: The clamping, or input, diode junction is the base emitter connection of a PNP transistor for clamping positive pulses and an NPN for clamping negative pulses. Instead of connecting the clamping diode junction to a fixed voltage chosen to cause clamping at the desired voltage, it is connected to the incoming signal on the emitter side while the other side, the base, is connected to a second diode junction, the other side of which is connected to fixed voltage, according to the invention. The second diode junction can be either the base emitter junction on a PNP or NPN as illustrated in the accompanying figures.

Preferably, to clamp positive going pulse, the base of clamping junction transistor is connected to the emitter of an NPN, or to the collector of a PNP, which in turn in the case of a PNP is also connected to its own base. In addition, the programming side of a current mirror is connected to the collector of the input transistor and to mirror the current flowing through the clamping diode junction to the second diode junction. The two diode junctions need not be the same size, but the current mirror system must be sized so that the current density in the two diode junctions is the same. When this is done, since the current density through the two junctions is the same, they will have the same changes in voltage for any current at any temperature. As a consequence, the limiting will occur at the fixed voltage, at all temperatures and input voltages, since the voltage drop across the diode junctions will cancel.

In accordance with the present invention, there is also provided in a preferred embodiment of the invention, a nearly ideal voltage clamp, constructed by compensating for the voltage changes across a diode junction used to clamp the voltage caused by temperature changes or changes in current through a clamping diode. In a preferred embodiment, the voltage clamp comprises a current mirror to match current densities in the bias and clamping transistors, thereby ensuring that the voltages across transistor junctions track each other when current flows through the clamping transistor, at any temperature, so that when the transistors are matched, then the voltage across the second junction is identical to that across the first junction whenever any substantial current flows in the clamping diode. If a new reference voltage is made by subtracting or adding, as appropriate, the voltages across a compensating diode which consists of the second junction referred to above, to a fixed voltage, then if the compensating diode is attached to this reference it will compensate for the changes in the clamping diode and the clamping voltage will be temperature independent and independent of current flowing thought the clamp so the clamping voltage will remain unaltered as the input voltage. Preferably the clamp is constructed as an integrated circuit, but may also be constructed using transistor arrays. If constructed as an integrated circuit a complementary bipolar process is preferably utilized. An injection of current into the programming side of the mirror is utilized to facilitate turning on the clamp and for the clamp to settle to the desired voltage rapidly. The present invention uses the current mirror to match the current densities in the bias and clamping transistors, thereby ensuring that the voltages across transistor junctions track each other when current flows through the clamping transistor, at any temperature.

This is best seen FIGS. 1, 7, 8, 9, 10, and 11, which illustrate preferred embodiments of clamp 10.

FIGS. 2, 3a, 4 and 5 illustrate prior simple clamps, voltage as a function of input voltage in a clamp, a first order temperature compensated clamp, and first order temperature compensated clamp outputs, and will be discussed in more detail below following a description of a preferred embodiment of the invention.

In the Figures and in this detailed description of preferred embodiments, note that Q1, Q2, Q3, and Q4 are described as transistors, they may, however, in various embodiments alternatively be diode connected transistors, or be the base emitter junctions of a transistor, or be a bias diode, bias transistor, clamping transistor, or the like.

Referring now to FIG. 1, a basic embodiment of the preferred embodiment of precision voltage clamp 10, is shown. In FIG. 1, to clamp the node X 12, at the junction of R1 20 and Q1 16, preferably, Q1 16, and Q2 26 are identically sized transistors, as are Q3 28, and Q4 30. If the voltage at node X 12, is less than that at Y 24, then essentially no current flows through Q116, and Vx=Vin. As soon as Vx exceeds Vy, Q1 16, will start to conduct and Q2 26, will carry almost the same emitter current as Q1 16. Note, there is a slight difference, due to base currents which is discussed below. Q3 28, is then forced to carry the same current density as Q2 26, since it has the same base emitter voltage as Q2 26. Thus the biasing transistor, Q4 30, carries the same current density as Q1 16, the clamping transistor, for all temperatures and input voltages that need to be limited so that the voltage drops across the base emitter junctions for Q1 16, and Q4 30, are always equal, and the clamping voltage at X 12, will always be the same as the voltage at Y 24.

The above description does not consider base currents, and a more exact treatment, including base currents shows if all four transistors Q1 16, Q2 26, Q3 28 and Q4 30, are the same size, then the emitter current in Q2 26, is actually I(1-4/β), where β is the ratio of the collector current to the base current, and is typically 100 or more. In practice, this term is less than 4 percent and since the current density only affects the temperature drift in second order, it is essentially negligible. It is also not a serious problem for the variation in clamping voltage with input voltage as long as β is constant over the current range of interest after limiting. This follows since a constant percentage difference in current leads to a constant offset in the clamp voltage, which is easily corrected when the clamp voltage is set.

The critical feature is to use a current mirror 32, to ensure that the current densities in the clamping transistor, Q1 16, in this case, and the bias correcting transistor, Q4 30, in this case, are very close to equal once the clamping action has begun.

In FIG. 1, the current source of a first order corrected clamp, is replaced with current mirror 32, made with transistors Q2 26, and Q3 28. This ensures the current through Q1 16 and Q4 30 is the same, no matter what current flows through Q1 16. So if Q3, 28 is the same as Q2 26, the same current flows through it since the base emitter voltage of Q3 28, is the same as that of Q2 26. The current comes from Q4 30, so Q4 will always carry the same current as Q1 16. Therefore, the voltage drops across the base emitter junctions for Q1 16 and Q4 30, will be identical for any input voltage. Note in the circuit shown in FIG. 4, there is not the same current flowing through the two transistors Q1 and Q2, which is why a correction will not work except at one particular input voltage. In fact, the sum of the current through Q1 and Q2 in FIG. 4 is constant.

In FIG. 1, before Q1 16, turns on, the dynamic input impedance at node X 12, is very high because Q1 16 and Q4 30, are carrying very little current and as a consequence below the clamping voltage the input impedance is higher than it is for a conventional clamp and Vx tracks Vin more closely than it would for a conventional clamp. Once Q1 16, goes into conduction, the input impedance is extremely low, zero in the ideal limit. This is true because as the input voltage rises causing the current to rise by δI. This causes the current in Q4 30, to rise by the same amount. Accordingly, the base emitter voltage of both Q1 16 and Q4 increase by the same amount, so the voltage at node X 12, does not rise at all, i.e. the dynamic impedance is zero. The base currents mentioned above, plus mismatches in the transistors will make the input impedance non-zero, but it will remain very small. This is a feed back effect. The change from high to low impedance is very rapid and the knee in the Vx vs. Vinput curve is so sharp that it appears discontinuous. This is seen in FIG. 6, which is a simulation of the circuit of FIG. 1 and shows the voltage at node X, plotted against the input voltage.

As discussed above, if base currents are included in the calculations then Q4 30, current is actually a factor of 1(1-4β) less than the emitter current in Q1 16, where β, as previously mentioned, is the ratio of the collector current to the base current, and is typically approximately 100 or more. This is countered by the fact that the currents do depend on the collector to base voltage to a small extent (finite Early Voltage). However, the differences in the currents are small, less than 5%, and since the current through the transistor only affects the transistor's base emitter voltage temperature coefficient in second order, this only provides an offset to the clamp voltage provided β is constant for the range of currents that will flow after clamping occurs. A slight mismatch in transistors has a similar effect. In FIG. 1, as the current densities in Q1 16 and Q4 30 are the same, it is possible to use a set of transistors where the ratio of the emitter areas of Q1 16, and Q2 26, is the same as the ratio of the emitter areas of Q4 30 and Q3 28, since then the current densities in Q1 16, and Q4 30 will be identical.

FIG. 2, shows a prior simple clamp for illustrative and comparative purposes. In FIG. 2, simple clamp circuit 50, consists of a diode connected transistor Q1 56, or string of diodes, connected in series, from the point, X 52, where the excursion is to be limited, to ground; while point X is connected to an input voltage source through a resistor, R1 54. Note, in FIG. 2, clamp circuit 50, is arbitrarily shown with a diode connected transistor Q1 56, rather than a diode. The operation of such clamp is described in all elementary electronics books. As the input voltage rises the current through the diode connected transistor rises, lowering the dynamic impedance of the diode connected transistor. Once this impedance becomes small compared to R1 54, voltage limiting at X 52 will set in. Also note, it is not necessary to use diode connected transistors, they could be replaced by diodes, or they could be the base emitter junctions of a transistor. The emitter can be tied to other voltages to change the clamping voltage.

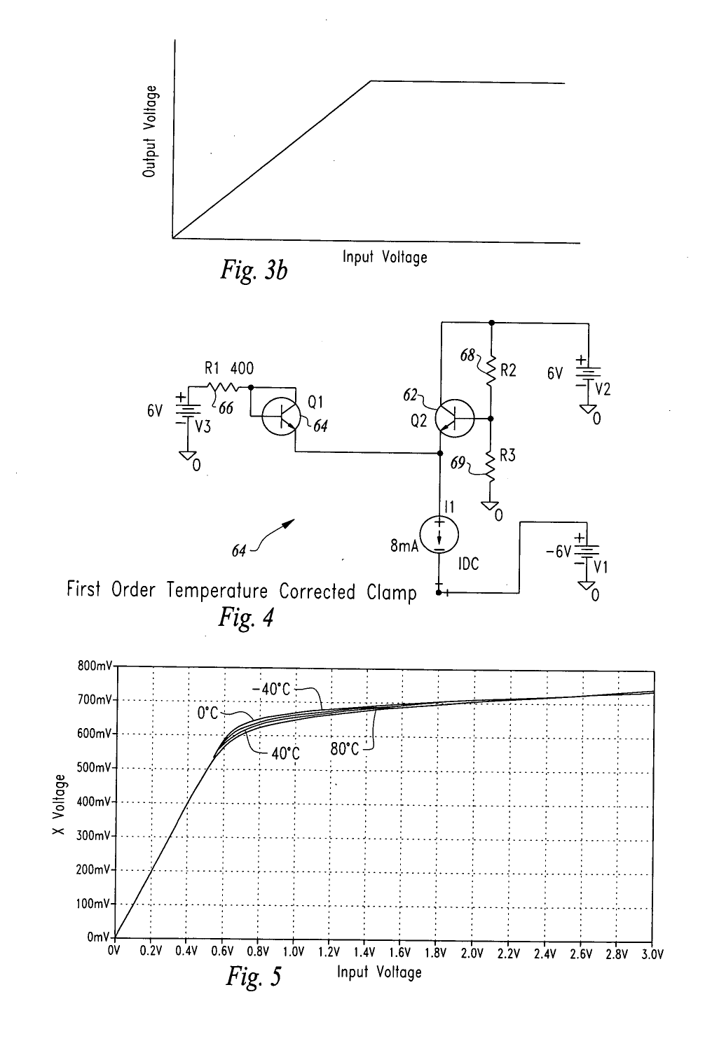

In FIG. 3(a) a graphic representation of the variation of clamping voltage varying with temperature and applied input voltage in a clamp such as shown in FIG. 4., is illustrated. FIG. 3(a) is the output of a SPICE simulation, 58. All simulations were done using SPICE and the components were from a Maxim CB2 process. There are three important points to notice in how FIG. 3a differs from that of an ideal clamp shown in FIG. 3(b). First it is seen how the clamping voltage depends strongly on temperature. Secondly, the clamping voltage continues to rise with increasing input voltage, even after the transistor goes into conduction. Thirdly, the transition of the voltage voltage at X from being equal to the input voltage for input voltages below the desired clamp voltage, to a constant voltage independent of the input voltage, is not sharp. For an ideal clamp, there is a discontinuous change in the slope for the curve from unity to zero at the desired clamp voltage as illustrated in FIG. 3(b).

It is seen in FIG. 3(a), that the temperature dependence comes from the fact that for a fixed current through a diode, the voltage drop across the diode changes by approximately −2 mv/degree C. The rise in the clamped voltage with increasing input voltage is a result of the increase in voltage across the diode as the current through the diode increases. This rise is logarithmic at first, but becomes linear at higher input currents when the dynamic impedance drops far below the intrinsic resistance of the material from which the diode is made. This rise is far less than it would be, were the diode not there, but it can become serious, particularly in integrated circuits where the diodes, or diode connected transistors, have a substantial intrinsic resistance.

FIG. 3(b), illustrates the case of an ideal clamp, where it is necessary to have the clamp limit at a voltage that is independent of temperature, and where the clamp voltage does not rise as the input voltage increases, i.e. the voltage at the desired point, X, needs to have the form as illustrated in FIG. 3(b), showing Vx vs. Vin for an ideal clamp.

As previously discussed, if an approximate logarithmic transfer function is required from an amplifier, one way of achieving this is to cascade a string of amplifiers (stages), each with gain G, each of which limits at the same output voltage, and to sum the outputs of all the amplifies in the cascade. The input may vary over several decades, and in this case, to maintain accuracy, it is essential that the limited output of a stage should be independent of the value of the input voltage for that stage, once it has acquired an input large enough to limit. Also, if the transfer function is to be temperature independent, the limiting voltages need to be temperature independent.

In FIG. 4, a first order temperature compensated clamp 60, is shown with transistors Q1 64, Q2 62, and R1 66, R2 68 and R3 69. In this circuit, the emitter Q2 62 is a very low impedance point since current is flowing through Q2 62. The voltage at the emitter of Q2 62 varies with temperature, because the base of Q2 62, is held at a fixed voltage, therefore as the temperature varies for a fixed current through a transistor, the base emitter voltage varies. This is the same effect that temperature has on the base emitter junction of Q1 64. When Q1 64, is in conduction the change in its base emitter voltage over temperature is exactly the reason that the curves seen in FIG. 3(a) vary so strongly with temperature. Thus, the shift in voltage of the emitter of Q2 62, compensates for the shift in the base emitter voltage of Q1 64, and the temperature shift in the curves should be cancelled. It is essential to run sufficient current in the current source to ensure that Q2 62, remains on even when Q1 64, is conducting and the Q1 64, current is going into the current source. Thus, the current source needs to draw a current that is larger than any current that could flow through Q1 64. This current needs to exceed (Vmax−Vbe)/R1, where Vmax is the maximum voltage that is put out by the voltage source that is the input to the circuit and Vbe is the base emitter voltage across Q1 64, when this maximum voltage is applied.

In FIG. 5, the output of a simulation of the circuit in FIG. 4, where clamp voltage vs. input voltage at four different temperatures −40 degrees C., 0 degrees C., 40 degrees C., and 80 degrees C., is illustrated. As can be seen In FIG. 5, there is a marked improvement over the response shown in FIG. 3(b). However, the cancellation is not perfect because the temperature drift in the base emitter voltage of a transistor carrying a specified current, has a second order dependence on the current density in the transistors, here Q1 64, and Q2 62. In this circuit Q1 64 and Q2 62, may be identical, but they only carry the same current for one particular value of the input voltage. In the circuit simulated in FIG. 4, this happens when the input voltage is at 2.4V, where the cancellation is essentially perfect. The curves cross there. In addition, it is noted that the clamped voltage does depend on the input voltage to a small degree, since Q1 64, base emitter base voltage difference will increase with increasing current.

FIG. 1 was previously discussed illustrating a basic embodiment of the preferred embodiment of a near ideal, or precision voltage clamp 10, of the present invention. In the embodiment shown in FIG. 1, as in other embodiments of the invention, the matching of transistors is important. This essentially requires that the clamp be built as an integrated circuit, or with transistor arrays, rather than using discrete components. If built as an integrated circuit, or as part of an integrated circuit, it is necessary to use a complementary bipolar process. The embodiment shown in FIG. 1, preferably uses 3 NPN transistors and 1 PNP, but may be otherwise. The matching of NPN and PNP transistors will not be as good as the matching of NPN's to each other, or PNP's to one another. It is noted, that even with poorly matched transistors, the precision clamp 10, of the present works well, but the voltage will require fine tuning. It should also be noted, that it is possible to overcome the PNP-NPN problem if it is serious for a given process, by adding a diode connected NPN in series with the PNP and a diode connected PNP in series with the NPN. Each are preferably put on the emitter side of the transistor in question.

In FIG. 6, the figure shows the results of a simulation of the circuit in FIG. 1, where the input voltage is varied form 0 to 3 volts and the clamp is set to clamp at 0.8V. The y axis is the voltage value at the clamped point, X 12, of FIG. 1. It actually clamps at 0.793V for the reasons previously discussed in relation to FIG. 1. The simulation run illustrated in FIG. 6 is for four different temperatures −40 degrees C., 0 degrees C., 40 degrees C., and 80 degrees C., and it is seen that there is barely any dependence on temperature. Further, the change in the voltage at X 12, once the clamp voltage was exceeded is negligible.

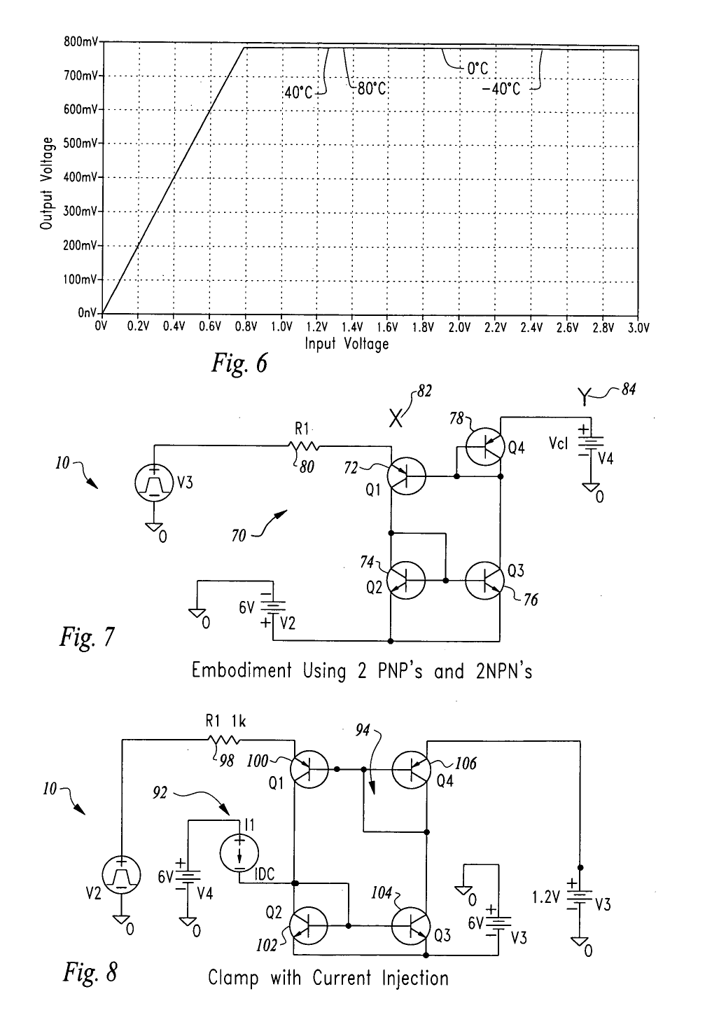

In FIG. 7, another preferred embodiment is shown as precision voltage clamp 10, which uses equal numbers of each type of transistor Q1, 72, Q2 74, Q3 76, Q4 78, and can be used if the matching of the two complementary types of transistors is not good enough. Node X 82, near R1 80 is shown, with node Y 84 and current mirror 86. The operation of clamp 70, in FIG. 7, is almost identical to the embodiment shown in FIG. 1, however, the embodiment in FIG. 7 does require a very low output impedance source to set the desired clamp voltage as it has to provide emitter current for Q2 74, rather than the base current, because node Y 84, is now the emitter of a transistor. In FIG. 7, preferably 2 PNP's and 2 NPN's are used rather than 3NPN's and 1 PNP. This has the advantage of having a PNP base emitter voltage cancel that of another PNP, rather than an NPN's base emitter voltage match that of a PNP. This will lead to better matching of the transistor base emitter voltages, since PNP's match PNP's, better than they do NPN's. The disadvantage is that the clamp voltage source needs a lower output impedance.

It is seen in the embodiments described in FIGS. 1 and 7, that a key to the invention is the use of a current mirror to achieve a temperature independent clamp that will maintain a clamping voltage over a large range of input voltages. It is noted that any current mirror may be used in the practice of this invention, and examples given herein are for illustrative purposes and are not meant to be limiting in their scope. There are several other factors to consider including this property of the clamp as well as optimize this property of the clamp as well as other factors that determine the speed with which the clamp will settle. These factors are discussed in detail below.

As previously mentioned, the clamp of the present invention will take a long time to settle, particularly if the applied voltage barely exceeds the clamp voltage. This is true because all the transistors are initially off, with the large junction impedances which makes it difficult to discharge stray capacitance rapidly. In order to overcome this problem it is necessary to inject a small bias current into the programming side of the mirror which will turn on the mirror and Q4 30 in FIG. 1 or Q4 78 in FIG. 7., making it much easier for the clamp to settle rapidly.

This is illustrated in FIG. 8, where clamp 10, has node R1 98, Q1 100, Q2 102, Q3 104, Q4 106, current mirror 94, and shows a current injection 92. This does degrade the temperature matching at voltages just at or just above clamping, where the added current makes the currents in the bias, and the clamping transistors slightly different. If the input voltage is raised and the current through all the transistors increases, the injected current becomes a small fraction of the total current, so the error becomes completely negligible. The main effect of the added current can be seen when one compares the ideal voltage out vs. voltage in curves, seen in FIG. 3b, to those obtained when the current is injected. The sharp corner seen when the nearly ideal clamp starts to clamp is slightly round, as seen in FIG. 12, and the rounding has a very slight temperature dependence. The effects are still far smaller than those seen with clamps using the prior art, as seen in FIG. 5. In FIG. 8, although the DC behavior is near ideal, there is a serious overshoot for large pulses, while small pulses, i.e. whose amplitude exceeds the clamp voltage by a small amount, take a very long time to settle. Injecting current 92, to keep Q2 102, Q3 104, and Q4 106 on slightly, largely solves this problem although DC response no longer has as sharp a knee.

The reason for the sharper corner is that once the system starts to switch on, the input impedance of the clamp of the present invention drops far faster than it does for a conventional clamp. In fact, if the bias transistor rise exactly matched that of the clamp transistor, the input impedance of the clamp would be zero. This sharp transition is highly desirable for some applications. For example, for a “Clamp amplifier” the ideal transfer goes from linear to limiting for as small an increase in the input pulse height as possible. Thus the rounding in the transfer curve induced by this injected current is undesirable and the injection current must be kept as low as possible to maintain the abrupt onset of limiting.

Preferred embodiments have been illustrated in FIGS. 1, 7, and 8. There are several additional ways of constructing current mirrors which may be utilized in preferred embodiments. The use of two other mirror types will be discussed. In addition, it is often advantageous to use mirrors which mirror the current up or down. For example, referring to the circuit in FIG. 1, it is possible to make Q3 28, and Q4 30, N times larger, or smaller than Q1 16, and Q2 26, where N is an arbitrary number preferably less than 20. In general Q1 16, and Q2 26, are made as small as possible to limit stray capacitance. Since they carry the same current, they are usually of equal size. This requires that the size of Q3 28, must be the same as the size of Q4 30. The advantage of making Q3 28, and Q4 30, smaller than Q1 16, and Q2 26, is that Q4 30, carries less current than it would if they were equally sized. This in turn requires less base current be fed into the base of Q4 30, which makes the load on VCLAMP lower, and allows a higher output impedance for VCLAMP, which saves power. The disadvantage is that the base current deficiency, discussed earlier with reference to FIG. 1, assumed all transistors were equally sized. If Q3 28, and Q4 30, are smaller than Q1 16, and Q2, 26, this deficiency is a larger proportion of the current through Q4 30, which degrades the cancellation slightly in the manner described in the explanation of FIG. 1. In addition the settling time is also lengthened when Q1 16, and Q2 26, are larger than Q3 28, and Q4 30. More importantly, it increases the settle time substantially so for fast settling it is better to make Q3 28, and Q4 30, larger than Q1 16 or Q2 26. However, as long as the ratio of the sizes of Q4 to Q1 is the same as the ratio of the sizes of Q3 to Q2, the current densities in Q1 and Q4 are identical (ignoring base currents) so the cancellation will still work.

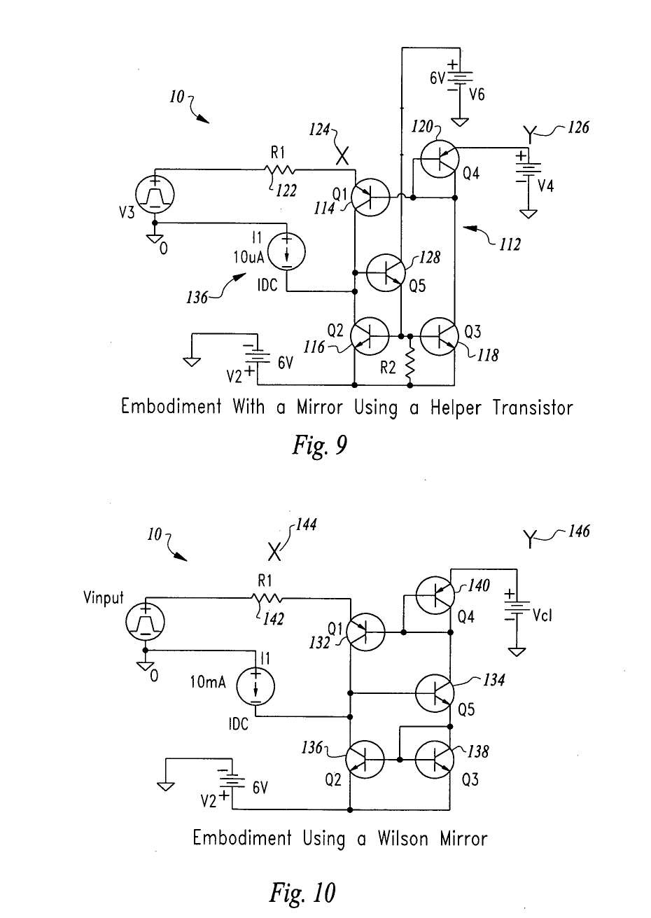

Referring now to FIGS. 9 and 10, preferred embodiments are shown using two other mirror types. In FIG. 9, a preferred clamp 10, is shown using a mirror 112, with helper transistor Q5 128. In FIG. 9, transistors Q1 114, Q2 116, Q3 118 and Q4 120 are also seen, with R1 122, X node 124, and Y node 126. In FIG. 9, a current injection 136, is used as previously described. As can be seen in FIG. 9, this preferred embodiment uses a different current mirror 112, one with a helper transistor Q5 128, and a resistor 142, to illustrate another form of mirror that can be used, according to the invention.

In FIG. 10, the current mirror shown for clamp 10, is a Wilson mirror 134, with Q3 138, and Q4 140, preferably a factor of 4 times larger than Q1 132, or Q2 136, and provides excellent results where settling speed and precision are important. Also shown are R1 142, node X 144, node Y 146, Wilson mirror transistor Q5 134, and current injection 148, according to the invention.

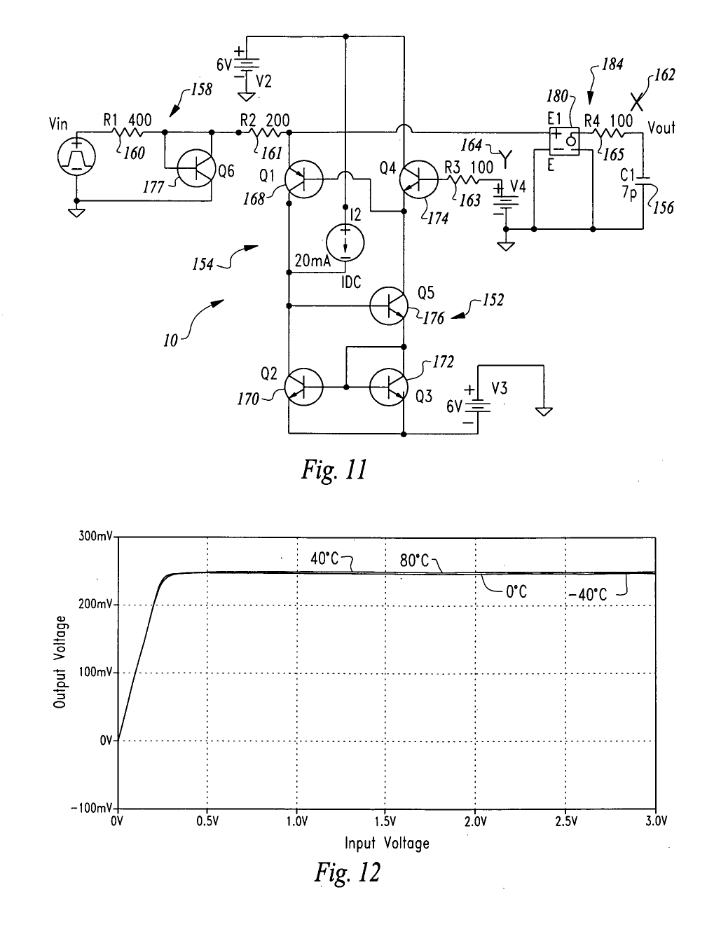

With reference now to FIG. 11, a clamp 10, according to a preferred embodiment is shown, which uses a Wilson mirror 152, has a current injection 154, and a low pass filter 156, which removes the sharp narrow overshoot that follows the onset of limiting. In FIG. 11, a simple clamp 158, is preferably placed in front of the main precision clamp 10, to lower the range of input currents the precision clamp has to limit. This lowers the currents in clamp 150 and saves power. Also seen is V1 160, Y node 164, X node 162, selected transistors, Q1 168, Q2 170, Q3 172, Q4 174, Q5 176, Q6 177, and R1 160, R2 161, R3 163, and R4 165, in clamp 10. Buffer amplifier E1 180, is connected to a low pass filter 184, comprising R4 165 and C1 156.

In FIG. 11, a preferred embodiment of clamp 10, is shown in an optimized embodiment, with excellent pulse response and a nearly ideal DC transfer curve. The cutoff is very sharp and there are very small over shoots for pulses. This is illustrated in FIGS. 12-14. The clamp in FIG. 11, uses simple clamp 158, made with Q6 177, and R1 160, before the mirrored clamp 10. The clamp point which was at the node where R2 161 attaches to Q1 168, is now taken thru buffer amplifier E1 180, to provide a low pass filter 184, comprising R4 165, operably linked to C1 156. The clamp point is now the junction of R4 165, and C1 156. These additional features provide a very clean and fast settling pulse. The preliminary clamp cuts down on overshoot which would be present with large input pulses. Additionally, filter 156, almost completely removes the overshoots. It is noted that the settling time after the remaining overshoot settles far faster than a simple RC overshoot, because it comes about because the initial input impedance is fairly high, but once current starts to flow, it goes to near zero input impedance so the “R” is reduced from the value it had at the start of the pulse. As a consequence the tail of the overshoot sees a continually decreasing RC time constant and settling is very rapid.

This is illustrated in FIGS. 12-14. In FIG. 12, the simulated DC transfer curve Vout vs. Vin, for the clamp of FIG. 11, is shown. All simulations were done using SPICE and components from the Maxim's CB2 process. The simulation of FIG. 12, was done at four temperatures, −40 degrees C., O degrees C. 40 degrees C., and 80 degrees C. Note that the curves lie on top on one another so there is essentially not temperature dependence. While the knee is not as sharp as it would be if the curve were ideal, it is still very sharp, and there is no rise in the clamping voltage as the input voltage is raised.

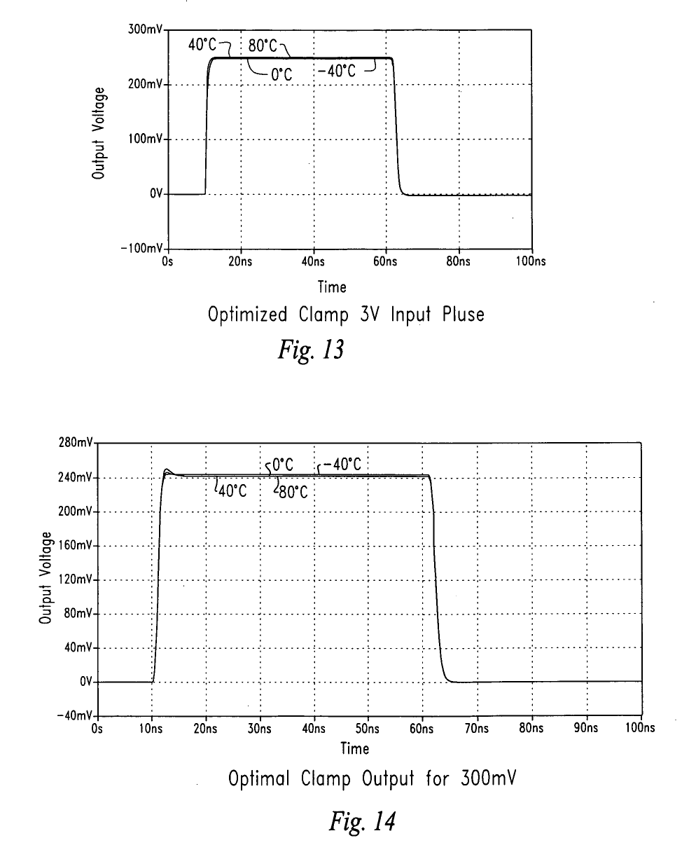

FIG. 13, is another simulation of the clamp of FIG. 11, which shows the response of the clamp 10, to a 3 volt input pulse for the four temperatures −40 degrees C., O degrees C. degrees C., and 80 degrees C. Note, the curves are essentially identical, and the circuit settles remarkably rapidly.

In FIG. 14, another simulation of clamp 10, of FIG. 11, is seen which shows the response of the clamp to a 300 mv input signal. Here, the effect of temperature at the start of the pulse is seen. However, it settles in under 3 ns and the difference between the clamp voltages at −40 degrees C., and 80 degrees C., is only 1.5 mv once the pulse has settled.

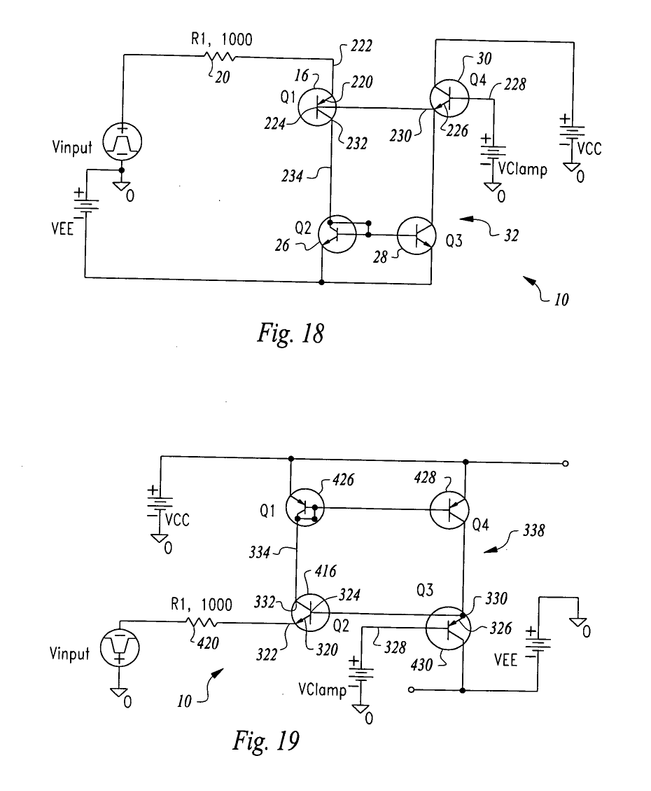

All of the embodiments of the invention discussed have been designed to clamp positive going pulses. They prevent positive going pulses from exceeding a certain maximum voltage, Identical principals apply to clamps designed to clamp a negative going pulse. To do so, one only has to replace all PNP's with NPN's and all NPN's with PNP's and to interchange positive and negative power supplies in order to make the conversion. In FIG. 19, an embodiment of the clamp of the present invention as shown in FIG. 18, is changed from one designed to clamp positive going pulse to one designed to clamp negative going pulses using just this technique.

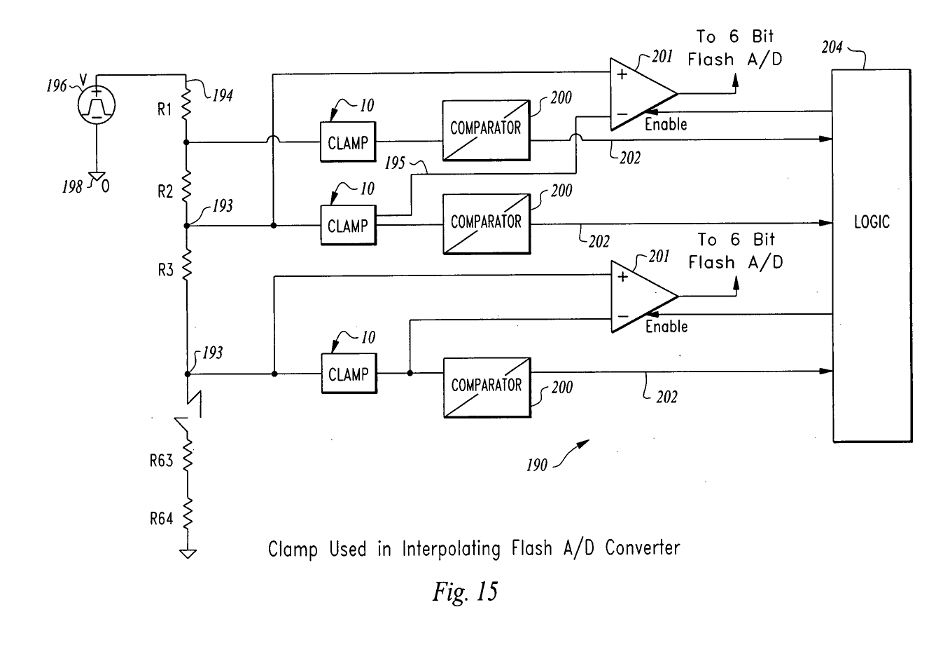

Another example of the operation of a preferred embodiment of the circuit, shown in FIG. 15, using clamps 10, to make a fast flash A/D converter using fewer parts than conventional designs. A clamp 10, is connected to each node 193, of a resistor chain 194, or net, with a plurality of equal resistors, R1 to R64, which has one end connected to a voltage input 196, and the other end grounded. The output of each clamp 10, is fed into one of a set of comparators 200, The comparators are set to fire if their inputs attain a value just below the limiting value of the clamps.

A second output 195, from each clamp is fed into a differential amplifier 201, whose other input comes from the input to the clamp. The outputs from comparators 200, and the differential amplifiers 201, are fed into a logic section 204. The logic registers which comparators switched and it identifies the highest comparator that fires, i.e. since the voltages going into each comparator are lower, the highest comparator is the one connected to the clamp between the highest numbered resistors. If the comparator between say R56 and R57, in chain or resistors 194, fires and the comparator between R57 and R58 does not fire, the highest comparator will be the one connected to the clamp attached to the node between R56 and R57. This provides the 6 highest order bits of the digital output of the A/D. The differential amplifier 201, connected to the input and the output of the highest one that fired, in this case the comparator connected to the node between R56 and R67, is enabled and the output of this goes into a standard 6 bit flash A/D to provide the lowest 6 bits. Logic 204, then combines and codes the 12 bits to give a 12 bit A/D converter that is extremely fast, and also requires far less circuitry than a standard 12 bit flash converter.

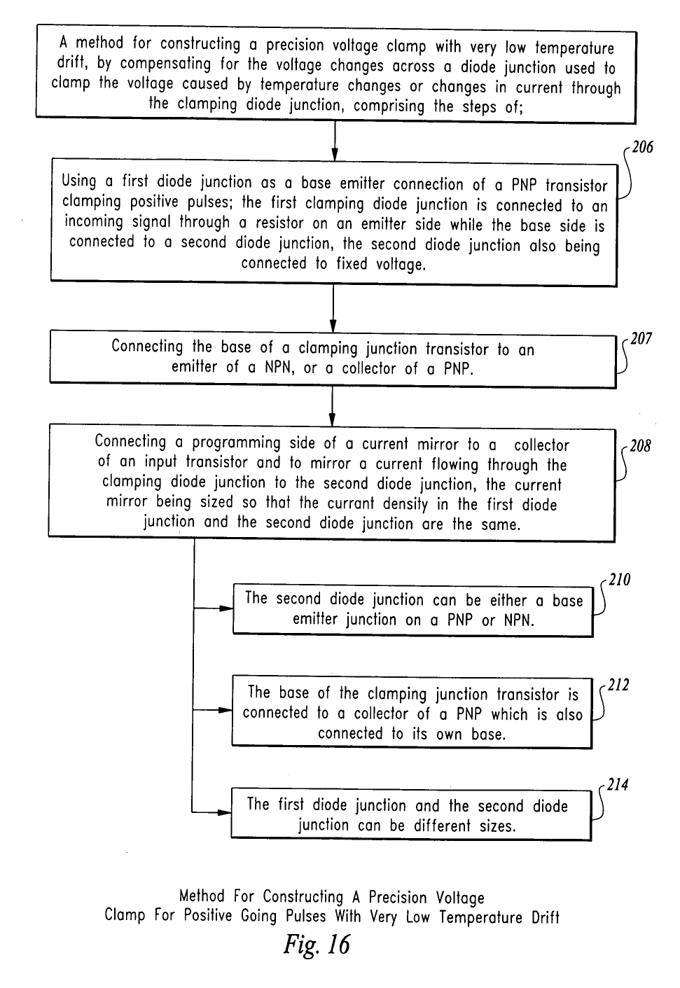

In FIG. 16, a flow diagram is shown of a preferred method for constructing a precision voltage clamp for positive going pulses with very low temperature drift, by compensating for the voltage changes across a diode junction used to clamp the voltage caused by temperature changes or changes in current through the clamping diode junction, comprising the steps of: using a first diode junction as a base emitter connection of a PNP transistor for clamping positive pulses; the first clamping diode junction is connected to an incoming signal on an emitter side while a base side is connected to a second diode junction, the second diode junction also being connected to fixed voltage, 206. Next, connecting the base of the clamping junction transistor to an emitter of an NPN, or a collector of a PNP, 207. Then, connecting a programming side of a current mirror to a collector of an input transistor and to mirror a current flowing through the clamping diode junction to the second diode junction, the current mirror being sized so that a current density in the first diode junction and the second diode junction are the same, 208. For negative going pulses the same methodology apples simply interchanging NPN and PNP.

In the preferred method illustrated in FIG. 16, for clamping positive going pulses, the second diode junction can be either a base emitter junction on a PNP or NPN, 210. The base of the clamping junction transistor is preferably connected to a collector of a PNP which is also connected to its own base 212. Preferably, the first diode junction and the second diode junction are of different sizes 214.

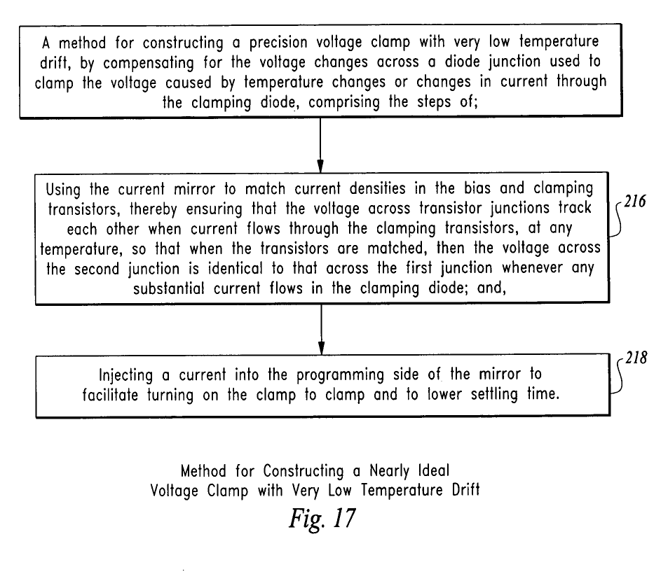

With reference now to FIG. 17. the low chart for another preferred method for constructing a precision and nearly ideal voltage clamp with very low temperature drift is shown. By compensating for the voltage changes across the diode junction used to clamp the voltage caused by temperature changes or changes in current through the clamping diode, comprising the steps of; using a current mirror to match current densities in the bias and clamping transistors, thereby ensuring that the voltages across transistor junctions track each other when current flows through the clamping transistors, at any temperature, so that when the transistors are matched, then the voltage across the second junction is identical to that across the first junction whenever any substantial current flows in the clamping diode, 216. Then, injecting a current into a programming side of the mirror to facilitate turning on the clamp to clamp and to settle rapidly, 218.

In FIG. 18, the embodiment illustrated is similar to that shown in FIG. 1, however, FIG. 18 more clearly illustrates a preferred clamping of positive going pulses according to the invention. FIG. 19, shows a preferred means for clamping negative going pulses.

With reference now to FIG. 18, a first diode junction 220, the clamping junction, of a PNP transistor 16, the emitter of first diode junction 220, having base side 224, is connected to resistor 20, the other side of which is connected to the input signal. The base side of the first diode junction 220, is connected to a second diode junction 226, the compensating junction, having base 228. This second junction is the base emitter junction 230, of an NPN transistor 30. The base 228, of the second diode junction is connected to a fixed voltage source, and the value of this voltage source determines the clamping voltage. The emitter side of the second junction, is connected to the base of the PNP transistor 16.

In FIG. 18, it is seen that the collector 232, of PNP transistor 16, is connected to the programming side 234, of current mirror 32, which preferably comprises the two NPN transistors 26 and 28. The current flowing through the PNP transistor 16, is mirrored to the output side of the mirror, the collector of the NPN transistor 28, which is also connected to the emitter side of the compensating diode junction 230, so that the same current density flows through both diode junctions. Note that the compensating diode junction and the clamping diode junction are not necessarily the same size. The mirror transistors are sized so that current densities in the clamping and compensating diode junctions are the same.

With reference now to FIG. 19, another preferred embodiment of nearly ideal voltage clamp 10, is shown. FIG. 19, illustrates a preferred clamping means for clamping negative going pulses, according to the invention. In FIG. 19, four transistors are shown 416, 426, 428 and 430. In FIG. 19, a first diode junction, the clamping junction, the base emitter junction 320, with emitter side 322, of NPN transistor 416, the emitter of first diode junction 326, is operably connected to a resistor 420, the other side of which is operably connected to the input voltage signal, while the base side of the first diode junction 324, is connected to a second diode junction 328. Second diode junction 328, is the base emitter junction of a PNP transistor. The base of the second diode junction is connected to a fixed voltage source, the value of which determines the clamping voltage. The emitter side of the second junction is connected to the base of the NPN transistor 416, the collector of the NPN transistor is connected to the programming side 334, of current mirror 338, which preferably comprises two PNP transistors 426 and 428. The current flowing through NPN 416, is mirrored to the output side of the mirror, the collector 332, of PNP transistor 428, which is also operably connected to the emitter side of the compensating diode junction 330, so that the same current density flows through both the clamping and compensating diode junctions. As discussed above, the compensating diode junction and the clamping diode junction are not necessarily the same size. The transistors are sized so that the current densities in the clamping and compensating diodes are the same.

In operation and use, the precision voltage clamp with very low temperature drift of the present invention is both highly effective and accurate and shows virtually no temperature dependence. Although specific examples of current mirrors have been given as examples in the detailed description, any current mirror may be used in the practice of this invention as described, and examples given herein are for illustrative purposes and are not meant to be limiting in their scope of breadth or application. The nearly ideal voltage clamp of the present invention may be used alone or in combination in a wide variety of circuits and applications.

Additional advantages and modification will readily occur to those skilled in the art. The invention in its broader aspects is, therefore, not limited to the specific details, representative apparatus and illustrative examples shown and described. Accordingly, departures from such details may be made without departing from the spirit or scope of the applicant's general inventive concept.

What is claimed is:

1. A nearly ideal voltage clamp, comprising:
a voltage source operably connected to at least one resistor;
at least two diode junctions, operably linked to said voltage source; and
a current mirror operably linked to said resistor, providing a nearly ideal voltage clamp, by compensating for the voltage changes across a diode junction used to clamp the voltage caused by temperature changes or changes in current through a clamping diode.

2. The nearly ideal voltage clamp of claim 1, wherein said nearly ideal voltage clamp further includes means for injecting a current into a programming side of said mirror to facilitate turning on said clamp to clamp and to settle more rapidly.

3. The nearly ideal voltage clamp of claim 1,
wherein said nearly ideal voltage clamp is constructed as an integrated circuit.

4. The nearly ideal voltage clamp of claim 3, wherein said integrated circuit utilizes a complementary bipolar process.

5. A nearly ideal voltage clamp, constructed by using a bias diode junction connected to the voltage source that sets the clamping voltage to compensate for the voltage changes across a diode junction used to clamp the voltage caused by temperature changes or changes in current through a clamping diode, comprising:
a current mirror to match current densities in the bias and clamping transistors, thereby ensuring that the voltages across transistor junctions track each other when current flows through the clamping transistor, at any temperature, so that when the transistors are matched, then the voltage across the second junction is identical to that across the first junction whenever any substantial current flows in the clamping diode.

6. The nearly ideal voltage clamp of claim 5, wherein if a new referenced voltage is made by subtracting or adding, as appropriate, said voltages across a compensating diode to a fixed voltage, then if said compensating diode is attached to this reference it will compensate for the changes in said clamping diode and the clamping voltage will be temperature independent and independent of current flowing through the clamp.

7. The nearly ideal voltage clamp of claim 5, wherein said clamp is constructed as an integrated circuit.

8. The nearly ideal voltage clamp of claim 7, wherein said integrated circuit utilizes a complementary bipolar process.

9. The nearly ideal voltage clamp of claim 5, wherein said clamp is constructed using transistor arrays.

10. The nearly ideal voltage clamp of claim 5, wherein an injection of current into a programming side of said mirror is utilized to facilitate turning on said clamp to clamp and to settle.

11. The nearly ideal voltage clamp of claim 5,
wherein said mirror is constructed to mirror the current up or down, by using a mirror which may mirror a higher or lower current and sizing said bias transistor so that the current density in it matches that of said clamping transistor.

12. The nearly ideal voltage clamp of claim 5, wherein said mirror is a Wilson mirror.

13. The nearly ideal voltage clamp of claim 5, wherein said clamp is utilized to clamp negative going pulses.

14. The nearly ideal voltage clamp of claim 5, where a plurality of said clamps are operably secured to a resistor chain running from a voltage input to ground; a comparator is communicatively secured to each clamp and to logic programming on the comparator outputs enabling a differential amplifier to communicate with a second chain of resistors, thereby providing a fast flash A/D converter using few parts and very little power.

15. An electronic circuit, comprising: a plurality of transistors to provide a precision voltage clamp that displays virtually no temperature dependence, and maintains a clamp voltage that varies by about 1 my for input voltages from the onset of clamping to several volts above this input, comprising;
a current mirror to match current densities in the bias and clamping transistors, thereby ensuring that the voltages across transistor junctions track each other when current flows through the clamping transistor, at any temperature, so that when the transistors are matched, then the voltage across the second junction is identical to that across the first junction whenever any substantial current flows in the clamping diode.

15. The electronic circuit of claim 15, wherein if a new referenced voltage is made by subtracting or adding, as appropriate, said voltages across a compensating diode to a fixed voltage, then if said compensating diode is attached to this reference it will almost exactly compensate for the changes in said clamping diode and the clamping voltage will be temperature independent and independent of current flowing through the clamp.

16. The electronic circuit of claim 15, wherein said clamp is constructed as an integrated circuit.

17. The electronic circuit of claim 15, wherein said integrated circuit utilizes a complementary bipolar process.

18. The electronic circuit of claim 15, wherein said clamp is constructed using transistor arrays.

19. The electronic circuit of claim 15, wherein an injection of current is utilized by injection of said current into a programming side of said mirror to facilitate turning on and settling of said clamp

20. The electronic circuit of claim 15, wherein said mirror is constructed to mirror the current up or down, by using a mirror which may mirror a higher or lower current and sizing said bias transistor so that the current density in it matches that of said clamping transistor.

21. A method for constructing a precision voltage clamp with very low temperature drift, by compensating for the voltage changes across a diode junction used to clamp the voltage caused by temperature changes or changes in current through the clamping diode junction, comprising the steps of:
using a first diode junction as a base emitter connection of a PNP transistor for clamping positive pulses and an NPN for clamping negative pulses; said first clamping diode junction is connected to an incoming signal on an emitter side while a base side is connected to a second diode junction, said second diode junction also being connected to fixed voltage;
connecting a base of a clamping junction transistor to an emitter of an NPN, or a collector of a PNP; and
connecting a programming side of a current mirror to a collector of an input transistor and to mirror a current flowing through the clamping diode junction to the second diode junction, said current mirror being sized so that a current density in the first diode junction and the second diode junction are the same.

22. The method for constructing a precision voltage clamp with very low temperature drift of claim 21, wherein said second diode junction can be either a base emitter junction on a PNP or NPN.

23. The method for constructing a precision voltage clamp with very low temperature drift of claim 21, wherein said base of said clamping junction transistor is connected to a collector of a PNP which is also connected to its own base.

24. The method for constructing a precision voltage clamp with very low temperature drift of claim 21, wherein said first diode junction and said second diode junction are different sizes.

25. A method for constructing a precision voltage clamp with very low temperature drift by compensating for the voltage changes across the diode junction used to clamp the voltage caused by temperature changes or changes in current through the clamping diode, comprising the steps of:
using a current mirror to match current densities in the bias and clamping transistors, thereby ensuring that the voltages across transistor junctions track each other when current flows through the clamping transistors, at any temperature, so that when the transistors are matched, then the voltage across the second junction is identical to that across the first junction whenever any substantial current flows in the clamping diode; and,
injecting a current into a programming side of said mirror to facilitate turning on said clamp to clamp and to settle more rapidly.

26. A nearly ideal voltage clamp for positive going pulses, constructed by compensating for the voltage changes across a diode junction used to clamp the voltage caused by temperature changes or changes in current through the clamping diode junction, comprising:
a first diode junction, a clamping junction, which is the base emitter junction of a PNP transistor; an emitter of said first diode junction is operably connected to a resistor to which one side thereof is connected to an input signal, while a base side of the first diode junction is connected to a second diode junction, a compensating junction; said second diode junction being connected to a fixed voltage source the value of said voltage source determines a clamping voltage; the emitter side of said second junction is connected to a base of said PNP transistor; and
a collector of said PNP transistor is operably connected to a programming side of a current mirror, which comprises two NPN transistors; a current flowing through the PNP transistor is mirrored to an output side of said mirror, the collector of said NPN transistor, which is also connected to an emitter side of the compensating diode junction, so that the same current density flows through both diode junctions.

27. A nearly ideal voltage clamp for negative going pulses, constructed by compensating for the voltage changes across a diode junction used to clamp the voltage caused by temperature changes or changes in current through the clamping diode junction, comprising:
a first diode junction, a clamping junction, which is a base emitter junction of an NPN transistor, the emitter of said first diode junction, is operably connected to a resistor, said resistor is also operably connected to an input voltage signal, while a base side of said first diode junction is connected to a second diode junction, a compensating junction;
said second diode junction is a base emitter junction of a PNP transistor, a base of said second diode junction is connected to a fixed voltage source, the value of which determines the clamping voltage; an emitter side of said second diode junction is connected to a base of the NPN transistor; a collector of said NPN transistor is connected to a programming side of a current mirror comprising two PNP transistors;
a current flowing through an NPN transistor is mirrored to an output side of said mirror, the collector of one of said PNP transistors, which is also connected to an emitter side of a compensating diode junction, so that the same current density flows though both sides of the diode junctions.
